(19) United States
(12) Patent Application Publication
(10) Pub. No.: US 2010/0027355 A1
(43) Pub. Date: Feb. 4, 2010

(54) PLANAR DOUBLE GATE TRANSISTOR STORAGE CELL

(76) Inventors: Thuy B. Dao, Austin, TX (US); Voon-Yew Thean, Austin, TX (US); Bruce E. White, Round Rock, TX (US)

Correspondence Address: FSI;c/o JACKSON WALKER, L.L.P., 100 CONGRESS AVENUE, SUITE 1100, AUSTIN, TX, 78701, US

(21) Appl. No.: 11/831,801

(22) Filed: Jul. 31, 2007

(51) Int. Cl. G11C 7/00; H01L 29/78; H01L 21/336

(52) U.S. Cl. 365/189.011; 257/314; 438/592; 257/E21.421; 257/E29.264

(57) ABSTRACT

A semiconductor device suitable for use as a storage cell includes a semiconductor body having a top surface and a bottom surface, a top gate dielectric overlying the semiconductor body top surface, an electrically conductive top gate electrode overlying the top gate dielectric, a bottom gate dielectric underlying the semiconductor body bottom surface, an electrically conductive bottom gate electrode underlying the bottom gate dielectric, and a charge trapping layer. The charge trapping layer includes a plurality of shallow charge traps, adjacent the top or bottom surface of the semiconductor body. The charge trapping layer may be of aluminum oxide, silicon nitride, or silicon nanoclusters. The charge trapping layer may located positioned between the bottom gate dielectric and the bottom surface of the semiconductor body.

### BACKGROUND

1. Field of Technology

This disclosure relates generally to semiconductor devices, and more specifically, semiconductor devices having storage cells.

2. Related Art

A dynamic random access memory (DRAM) is a volatile storage device that is generally arranged as an array, i.e., rows and columns, of cells where each cell represents a binary digit (bit). It is desirable to minimize the size of the cell to achieve high bit densities and reduce the size and cost of the device. DRAM cell technology is sometimes characterized by the number of transistors that the cell employs. A 1T cell, for example, is a DRAM cell that includes only a single transistor. Reducing the number of transistors in a cell is desirable to minimize the size of the cell.

For advanced technology platforms, such as the 32 nm platform in which the half pitch of a memory cell is 32 nm, advanced techniques will be required to achieved adequate performance. For example, some prior 1T DRAM cells use a transistor that has a double gate, a first gate in contact with a first surface of the transistor body and a second gate in contact with a second surface channel. Unfortunately, existing 1T DRAM double gate devices, use the wafer's silicon substrate as the back gate to form a floating body storage node or use the back gate bias to create floating body storage node. These type of devices have low charge storage and limited control of DRAM performance. Thus, there is a need for a new structure and method to increase charge storage and improve data retention.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is a partial cross section of a donor wafer at a selected stage in one embodiment of a fabrication process to produce a one transistor cell suitable for use in advanced technology DRAM devices;

FIG. 2 depicts processing subsequent to FIG. 1 in which a hole trap layer is formed overlying the donor wafer;

FIG. 3 depicts processing subsequent to FIG. 2 in which a bottom gate dielectric is formed overlying the donor wafer;

FIG. 4 depicts processing subsequent to FIG. 3 in which a bottom gate layer is formed overlying the donor wafer;

FIG. 5 depicts processing subsequent to FIG. 4 in which the bottom gate layer is patterned to form a bottom gate structure and isolation structures are formed adjacent the bottom gate structure;

FIG. 6 depicts processing subsequent to FIG. 5 in which a dielectric layer is formed overlying the donor wafer;

FIG. 7 illustrates a partial cross section of a handle wafer including a dielectric layer overlying a semiconductor layer;

FIG. 8 depicts processing in which the dielectric layer of the donor wafer is bonded to the dielectric layer of the handle wafer to form a product wafer;

FIG. 9 depicts processing subsequent to FIG. 5 in which the product wafer is cleaved to form a transistor body layer overlying the bottom gate structure; and

FIG. 10 depicts processing subsequent to FIG. 9 in which isolation regions are formed in the transistor body layer, a top gate structure is formed overlying the bottom gate structure, and source/drain regions aligned to the top gate structure are formed in the transistor body layer.

### DETAILED DESCRIPTION

In one aspect, a planar double gate (PDG) storage cell is disclosed. The PDG cell includes a top gate electrode overlying a top gate dielectric overlying a semiconductor body overlying a bottom gate dielectric overlying a bottom gate electrode. The bottom gate electrode may overlie a buried oxide layer. The cell as disclosed includes a charge trapping layer near an upper or lower surface of the semiconductor body to store charges that alter the device threshold voltage. The differing threshold voltage enables a sensing circuit to distinguish at least two states of the cell thereby forming the basis of a binary state cell. The charge trapping layer may be formed near the surface of the bottom gate. The charge trapping layer may include a suitable dielectric material or isolated conductive spheres or other structure.

In another aspect, a method of fabricating a storage cell is disclosed. Some embodiments of the fabrication techniques disclosed include forming a gate dielectric on a surface of a bottom gate layer and thereafter forming a charge trapping layer on the gate dielectric. The charge trapping layer may include a large number of shallow charge traps, e.g., shallow hollow traps suitable for removably storing charge. The charge trapping layer may be an insulator, e.g., aluminum oxide or silicon nitride. In other embodiments, the hole trapping layer may include isolated particles or nanoclusters of a conductive material such as silicon. The transistor body of the double gate transistor is then formed overlying the hole trapping layer and the top gate dielectric, top gate, and the associated sourced/drain structures are formed.

In another aspect, a method of operating the embodied semiconductor device as a storage cell is disclosed. The method includes writing the cell by biasing a top gate electrode overlying a top gate dielectric and a semiconductor body to a first top gate write voltage, biasing a bottom gate electrode underlying a bottom gate dielectric underlying the semiconductor body to a first bottom gate write voltage, biasing a drain electrode laterally positioned adjacent to a transistor channel of the semiconductor body underlying the first gate electrode to a first drain write voltage, and biasing a source terminal laterally positioned adjacent the transistor channel to ground. The method further includes reading the cell by biasing the top gate electrode to a top gate read voltage, biasing the bottom gate electrode to a bottom gate read voltage, biasing the drain electrode to a drain read voltage, and biasing the source terminal laterally positioned adjacent the transistor channel to ground. The method may further include writing a second value in the storage cell by biasing the top gate electrode to a second top gate write voltage, biasing the bottom gate electrode to a second bottom gate write voltage, biasing the drain electrode to a second drain write voltage, and biasing the source terminal to ground. The disclosed method of writing the storage cell includes storing charge in a charge trapping layer of the device. The charge trapping layer is located in close proximity to a surface of the semiconductor body and may include a plurality of shallow hole traps. In NMOS embodiments using shallow holes traps, the first top gate write voltage is approximately 0.6 V, the first bottom gate write voltage is approximately −2.0 V, the first drain write voltage is approximately 1.8 V, said second top gate write voltage is approximately 1.0 V, said second bottom gate write voltage is approximately −0.5 V, and said second drain write voltage is approximately −1.0 V. The top gate read voltage is approximately 0.6 V, said bottom gate read voltage is approximately −1.5 V, and said drain read voltage is approximately 0.2 V.

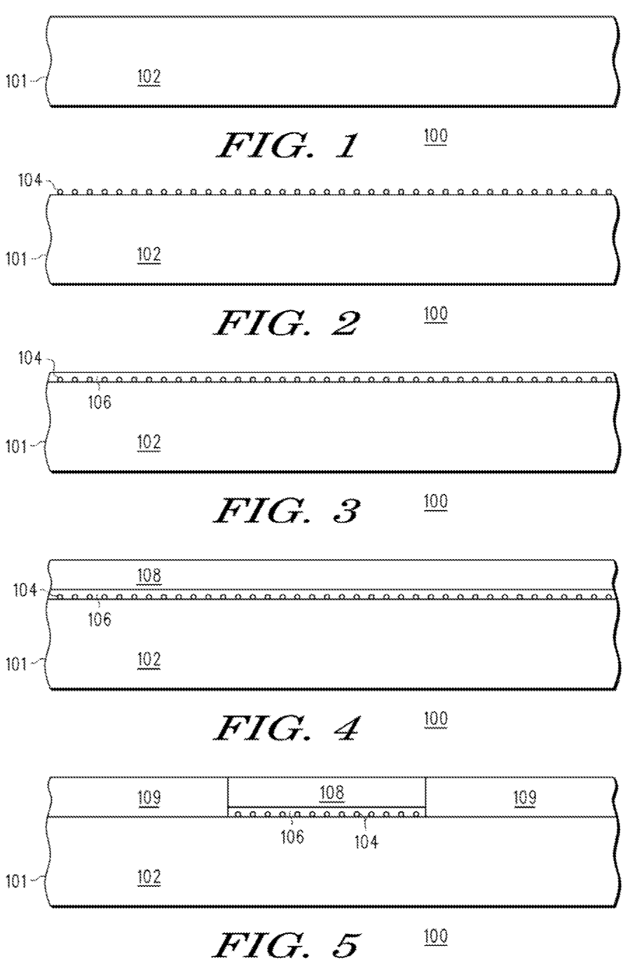

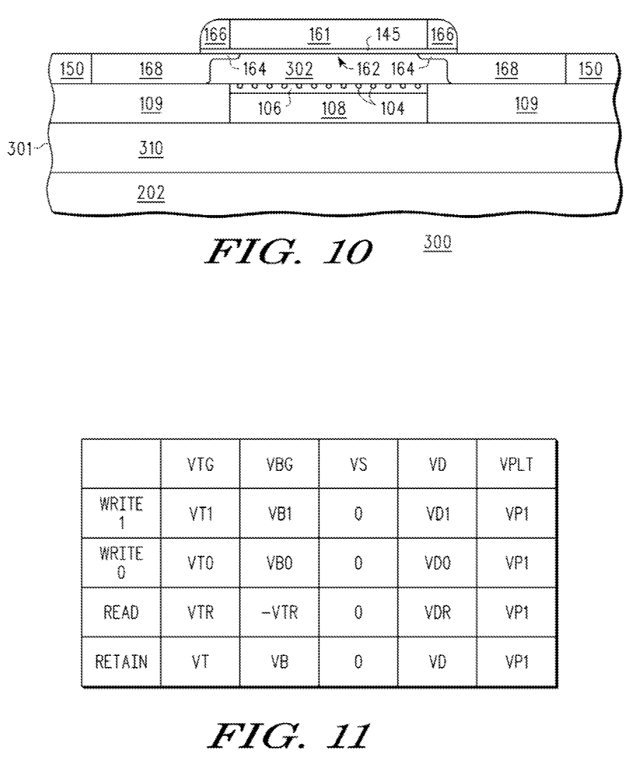

Referring now to FIG. 1 through FIG. 10, wafer cross sections emphasizing selected stages in one embodiment of a fabrication process suitable for producing a storage cell are illustrated. The depicted embodiment of the fabrication process includes forming a storage cell having a PDG transistor that incorporates a charge trap material in the bottom gate dielectric to improve the storage characteristics of the resulting cell. As illustrated in the drawings, the formation of the PDG transistor includes bonding two wafers, referred to herein as the donor wafer and the handle wafer, to form a product wafer. Processing of the donor wafer is illustrated in FIG. 1 through FIG. 6. The handle wafer is illustrated in FIG. 7. The bonding of the two wafers to form the product wafer is illustrated in FIG. 8. Subsequent processing of the product wafer to form the storage cell is illustrated in FIG. 9 and FIG. 10.

Referring now to FIG. 1, a partial cross sectional view of a donor wafer 101 is illustrated. As shown in FIG. 1, donor wafer 101 includes a semiconductor layer 102. In the embodiment of the fabrication illustrated herein, portions of semiconductor layer 102 will serve as the body of a PDG transistor.

In some embodiments, semiconductor layer 102 is a substantially single crystal layer of a semiconductor material suitable for use in a solid state device. Semiconductor layer 102 may, for example, be a single crystal silicon layer or a layer of another semiconductor such as gallium arsenide. Semiconductor layer 102 may be the bulk substrate layer of donor wafer 101. In other embodiments, semiconductor layer 102 may be an active layer of a silicon on insulator (SOI) donor wafer 101 in which semiconductor layer overlies a buried oxide (BOX) layer (not depicted), which may overlie a bulk or substrate layer (not depicted). In embodiments that employ a silicon semiconductor layer 102, semiconductor layer 102 may be an undoped layer, a doped n-type or p-type layer, or a combination thereof.

Referring now to FIG. 2, a charge trapping layer 104 is formed overlying semiconductor layer 102 of donor wafer 101. Charge trapping layer 104 includes a prevalence of charge traps. Although the charge traps of trapping layer 104 may be hole traps or electron traps and although the charge traps may be characterized as either deep hole traps, e.g., traps having an activation energy exceeding 1.5 eV or shallow traps, i.e., traps having an activation energy less than or equal to 1.5 eV, embodiments suitable for use with NMOS transistor storage cells employ a charge trapping layer 104 that has a prevalence of shallow hole traps and, still more preferably, shallow hole traps characterized by an activation energy of approximately 0.3 eV or less. In some embodiments, the density of shallow charge traps in charge trapping layer 104 exceeds a specified threshold. In some embodiments, a suitable threshold is for the storage trap density is approximately 1E12 (1×10¹²) charge traps/cm².

In the embodiments that employ an NMOS PDG transistor for the storage cell and in which the charge trapping layer 104 is implemented as a hole trap layer that facilitates the trapping of holes near the interface of a structure that will ultimately serve as the bottom gate structure in the PDG transistor, the presence of hole trapping sites near the bottom gate interface of the PDG, coupled with the ability to bias separately the two gates of a PDG transistor, improves the ability of the PDG transistor to retain stored charge in the transistor body and thereby improve the retention of data. In addition, while the resulting storage cell is still dynamic in the sense that periodic refresh of cell is needed, an advantage of the double gate implementation is that different gates can be used for read and storage operations so that, for example, reading data from the resulting storage cell might be a non-destructive operation, i.e., an operation that does not alter the stored data.

In some embodiments, charge trapping layer 104 includes or consists entirely of a monolayer or a few monolayers of aluminum oxide or silicon nitride. In these embodiments, charge trapping layer 104 may be formed with an atomic layer deposition (ALD) process. In other embodiments, charge trapping layer 104 is fabricated using discrete spheres or structures of a conductive material such as doped or undoped silicon or a doped or undoped silicon compound. Such discrete spheres or structures may be referred to herein as nanoclusters and silicon implementations of the nanoclusters may be referred to as silicon nanoclusters. Nanoclusters may be formed directly on semiconductor body 102 or on a thin silicon oxide or other dielectric film that is formed before forming the nanoclusters. Regardless of the implementation of its materials, charge trapping layer 104 facilitates the trapping of carriers near the interface between the bottom gate and the transistor body. By appropriate use of materials and biasing of the transistor gates, charge trapping layer 104 is operable as a hole trapping layer in an NMOS implementation of the PDG transistor.

Referring to FIG. 3, a bottom gate dielectric 106 is formed overlying semiconductor layer 102 and charge trapping layer 104. In some embodiments, bottom gate dielectric 106 is substantially stoichiometric silicon dioxide (SiO₂) formed with a thermal oxide formation process as is well known. In other embodiments, bottom gate dielectric 106 may include or consist of one or more alternative dielectrics. For example, bottom gate dielectric 106 might, in some embodiments, include a high K dielectric, e.g., hafnium oxide or any other suitable material having a dielectric constant greater than the dielectric constant of silicon dioxide, e.g., silicon nitride. The effective oxide thickness of bottom gate dielectric 106 is an implementation detail, but, in some embodiments is in the range of approximately 1.0 to 5.0 angstroms.

Turning to FIG. 4, a bottom gate layer 108 is formed overlying bottom gate dielectric layer 104. As suggested by its name, bottom gate layer 108 will ultimately function as the bottom transistor gate electrode in the disclosed PDG transistor. Bottom gate layer 108 is a conductive layer that may be a polycrystalline silicon (polysilicon) layer formed according to any of various well known polysilicon deposition techniques including, for example, deposition by thermally decomposing silane or another silicon bearing species. In polysilicon embodiments of bottom gate layer 108, the polysilicon may be lightly or heavily doped, and/or p-type or n-type doped to achieve a desired polarity and conductivity. In doped polysilicon embodiments, the doping may occur in situ or after bottom gate layer 108 is deposited by, e.g., ion implantation, diffusion, or another suitable technique. In other embodiments, bottom gate layer 108 may include or consist of polycrystalline silicon, α-silicon, α-germanium and/or a metal or metal alloy, e.g., W, Ti, Ta, TiN, TaSiN, and silicide, a combination thereof, or another suitable metal. A thickness of bottom gate layer 108 is an implementation detail but, in some embodiments, may be in the range of approximately 1000 to 1500 nm.

Referring to FIG. 5, bottom gate layer 108 has been patterned to form bottom gate electrode 111 and isolation regions 109 have been formed laterally displaced on either side of bottom gate electrode 111. Patterning of bottom gate layer 108 to form bottom gate electrode 111 may include conventional lithography and etch processing to remove the exterior portions of bottom gate layer 108 as shown in FIG. 5. The isolation regions 109 may then be formed, for example, by nonselectively depositing a low temperature oxide (LTO) or other suitable dielectric material and thereafter planarizing the topography with a selective etchback, chemical mechanical polish, another suitable planarizing process, or a combination thereof. In the embodiment depicted in FIG. 5, the planarization processing results in a substantially planar surface that includes an upper surface of bottom gate electrode 111 and the upper surfaces of the isolation regions 109.

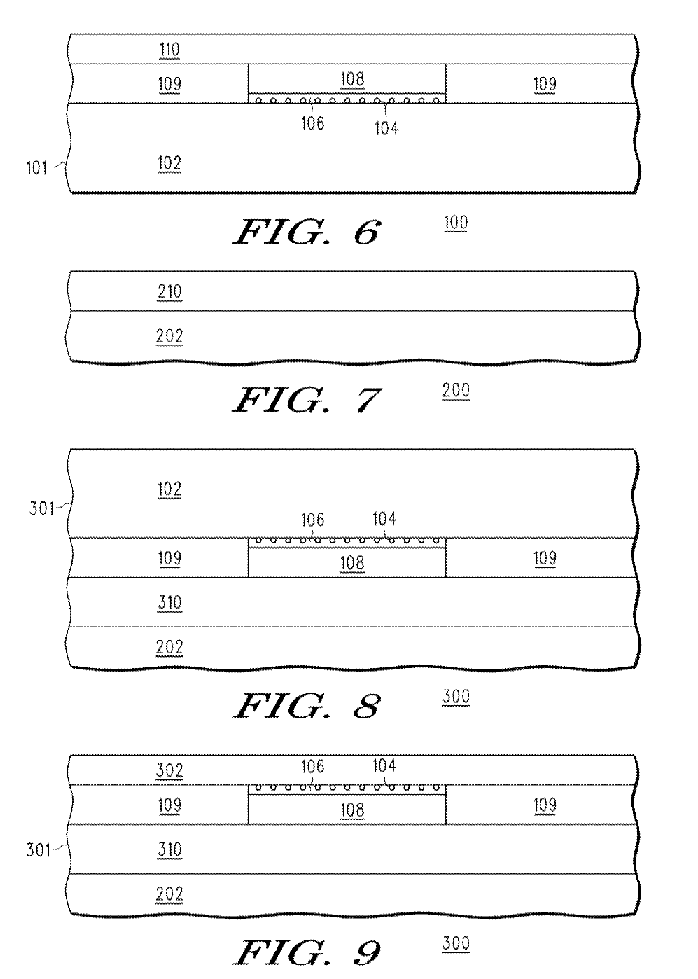

Referring now to FIG. 6, a bonding layer 110 is deposited overlying bottom gate electrode 111 and isolation regions 109. Bonding layer 110 is of a material that is suitable for bonding donor wafer 101 to another wafer. In some embodiments, bonding layer 110 is a chemically vapor deposited dielectric such as a TEOS-based silicon oxide. Other embodiments may form a CVD silicon oxide using a different species, by thermal oxidation, by spin depositing a spin-on glass (SOG), and so forth as will be appreciated by one of ordinary skill in semiconductor fabrication. Alternatively, bonding layer 110 may be a silicon nitride, silicon oxynitride, or other form of electrically insulating compound. Like the composition of bonding layer 110, the thickness of bonding layer 110 is an implementation detail, but may be in the range of approximately 20 to 50 nm. As depicted in FIG. 6, donor wafer 101 is ready for bonding to a handle wafer.

Referring to FIG. 7, a handle wafer 201 suitable for bonding with donor wafer 101 according to one embodiment of a process to form the disclosed PDG transistor is illustrated. As shown in FIG. 7, handle wafer 201 includes a bonding layer 210 overlying a substrate 202. Like the bonding layer 110 of donor wafer 101, bonding layer 210 of handle wafer 201 may be a dielectric layer that includes or consists of a thermally formed, CVD, or spin-deposited silicon oxide compound. In other embodiments, bonding layer 210 may be an alternative dielectric such as a silicon nitride layer or a silicon oxynitride. In some embodiments, the bonding layer 210 of handle wafer 201 and the bonding layer 110 of donor wafer 101 are of the same or substantially the same composition. In other embodiments, the two bonding layers may be of different composition.

Substrate 202 will provide mechanical support for the product wafer in which the disclosed PDG transistor cell is formed. Substrate 202 may include one or more layers of a semiconductor material such as silicon, a dielectric material such as silicon oxide, or a conductive material such as a metal or metal compound. In some embodiments, substrate 202 represents the bulk substrate of a conventional silicon wafer. In other embodiments, multiple layers of various materials may exist below the portion of substrate 202 I shown in FIG. 7.

Referring to FIG. 8, donor wafer 101 as shown in FIG. 6 is bonded to handle wafer 201 as shown in FIG. 7 to form product wafer 301 as shown in FIG. 8. The orientation of donor wafer 101 as shown in FIG. 8 is rotated 180° from the orientation shown in FIG. 6 so that donor wafer 101 has been flipped and bonded to handle wafer 201. In the depicted embodiment, bonding layer 110 of donor wafer 101 is bonded to bonding layer 210 of handle wafer 201 to form a buried oxide layer (BOX) layer 310 in product wafer 301. The bonding of layers 110 and 210 may include heat bonding, pressure bonding, a combination of both, or another suitable wafer bonding process. A process for making a traditional PDG transistor including a wafer bonding process is described, for example, in U.S. Pat. No. 7,141,476 to Dao et al. entitled Method of Forming a Transistor with a Bottom Gate.

Turning now to FIG. 9 a portion of the semiconductor layer 102 of product wafer 301 has been removed to form a semiconductor body 302. In some embodiments, formation of semiconductor body 302 includes cleaving product wafer 301 along a plane within semiconductor layer 102. In such embodiments, the cleaving process may be facilitated or assisted by creating a cleaving plane with semiconductor layer 102. In some embodiments, the cleaving plane (not depicted) is created by ion implanting a layer of an electrically inert or other type of species into semiconductor layer 102 to create a thin region in layer 102 that has a large number of broken bonds. In these embodiments, creation of the cleaving plane may occur at various stages, but in at least one embodiment, the cleaving plane is created prior to forming charge trapping layer 104 as described previously with respect to FIG. 2. In alternative embodiments, creation of semiconductor body 302 may be achieved by or include etching back and/or polishing semiconductor layer 102.

In some embodiments, semiconductor body 302, being formed from semiconductor layer 102, is single crystal or substantially single crystal silicon. Semiconductor body 302 may be an intrinsic or undoped semiconductor. Alternatively, semiconductor body 302 may also be implanted or diffused with various species, e.g., phosphorous, arsenic, or boron, to create a desired work function and/or conductivity. Semiconductor body 302 may also include species, e.g., germanium or carbon, that form strain inducing compounds with silicon to alter the stress characteristics of semiconductor body 302. These various species may be introduced into semiconductor body 302 uniformly or non-selectively. Alternatively, such species may be introduced non-selectively into semiconductor body 302 using, e.g., a conventional photoresist mask or hard mask.

As shown in FIG. 9, semiconductor body 302 has a bottom surface 303 and a top surface 304. Bottom surface 303 is in contact with and/or forms an interface with charge trapping layer 104. Top surface 304 will be in contact with and/or form an interface with a top gate dielectric described below. In a fully depleted design of the DPG transistor cell, the thickness of semiconductor body 302 may be in the range of approximately 50 to 100 nm.

Turning now to FIG. 10, processing subsequent of FIG. 9 has produced an operable PDG transistor storage cell 300. As shown in FIG. 10, exterior portions of semiconductor body 302 have been removed and isolation regions 150 have been formed laterally displaced on either side of the remaining portion of semiconductor body 302. In addition, a top gate structure 160 has been formed by forming a top gate dielectric layer 145 overlying semiconductor body 302 and a top gate electrode 161 overlying top gate dielectric 145. Spacer structures 166 have been formed on sidewalls of top gate electrode 161 and the semiconductor body 302 has been processed to form s/d regions 168 and extension regions 164. As shown in FIG. 10, bottom gate dielectric 106 underlies bottom surface 303 of semiconductor body 302 and electrically conductive bottom gate electrode 108 underlies bottom gate dielectric 106.

Isolation regions 150 may include or consist of a CVD silicon oxide formed in a manner similar to the formation of isolation regions 109. Like bottom gate dielectric 106, top gate dielectric 145 may include or consist of a thermally formed silicon dioxide, an alternative gate dielectric material including a high-K dielectric material, or a combination thereof. An effective oxide thickness of top gate dielectric 145 is an implementation detail, but may be in the range of 1 to 5 nm. The effective oxide thickness, composition, and dielectric constant of top gate dielectric 145 is independent of the effective oxide thickness, composition, and dielectric constant of bottom gate dielectric 106. As such, the values of those parameters may differ from or be the same as the parameters for bottom gate dielectric 106. In the depicted embodiment, however, the bottom gate electrode 111 includes charge trapping layer 104 whereas top gate structure 160 does not. Alternative embodiments may incorporate charge trap layers at both gate dielectric interfaces or at the top gate dielectric interface only. Moreover, in embodiments that include charge trap layers at both interfaces, the layers may be of different materials and may be designed to trap opposite types of carriers.

Top gate electrode 161 is an electrically conductive electrode that may be a conventional doped polysilicon or metal gate electrode. The composition, dimensions, work function, and other characteristics of top gate electrode 161 may differ from or be the same as bottom gate electrode 108. In the depicted embodiment, the length (L) of the two gate electrodes is substantially the same and the sidewalls of the two electrodes aligned to each other. In other embodiments, the bottom gate electrode may extend beyond the boundaries defined by the top gate so that, for example, a contact to the bottom gate electrode may be formed. The extension regions 164 and source drain regions 168 are preferably self aligned to top gate electrode 161 by creating regions 164 and 168 after top gate electrode 108 has been patterned. As an example, extension regions 164 may be formed after top gate electrode 161 is patterned, but prior to the formation of spacers 166. The spacer structures 166, typically made of silicon oxide or another dielectric, may then be formed on sidewalls of top gate electrode 161 by depositing a conformal layer of dielectric and non-isotropically etching the deposited layer in a well known manner. After formation of spacers 166, source drain regions 168 are formed self aligned to top gate structure 160, including spacers 166, by ion implanting boron, phosphorous, or arsenic depending on the type of transistor. In an NMOS implementation, for example, The PDG transistor storage cell 300 includes a lightly doped p-type transistor body 162 laterally displaced between heavily n-doped (n+) source drain regions 168 and lightly doped (n−) extension regions 164.

PDG transistor storage cell 300 as shown further includes a charge trapping layer 104. As described previously, charge trapping layer 104 includes a prevalence of shallow charge traps which may include hole traps, electron traps, or a combination of both. In at least some embodiments suitable for use with NMOS storage cell implementations, the charge traps of charge trapping layer 104 are predominantly hole traps. In some embodiments, bottom gate electrode 106 and top gate electrode 161 may be biased independently of one another. In these embodiments, PDG transistor storage cell 300 is a four terminal device that may further include a mechanism to bias the substrate 202. In embodiments designed for use as DRAM storage cells, the four electrodes may be biased to achieve four or more functions as illustrated in the function table depicted in FIG. 11. As shown in FIG. 11, PDG transistor storage cell 300 may be biased to write a “1,” write a “0,” read, or retain the data depending on the biasing of the cell.

A “1” is written by biasing top gate electrode 161 to a top-gate-1 voltage (VT1), bottom gate electrode 108 to a bottom-gate-1 voltage (VB1), one of the source/drain electrodes 168 to a drain-1 voltage (VD1), and the other source/drain electrode 168 to ground (0 V). Although the values suitable for VT1, VB1, and VD1 are implementation specific, some NMOS embodiments, i.e., embodiments in which the transistor body is a p-type semiconductor, may specify nominal values of VT1, VB1, and VD1 as 0.6 V, −2.0 V, and 1.8 V respectively. The negative bias applied to back gate 108 creates an accumulation of holes at the interface between bottom gate dielectric 106 and semiconductor body 302 so that body 302 functions as an electrically contiguous but isolated body, i.e., a floating body. The biasing of top gate electrode 161 and drain electrode 168 results in the creation of hot carriers being injected into floating body 302, where the presence of charge trapping layer 104 facilitates the trapping of these charges thereby “programming” the cell by altering the threshold voltage.

A “0” is written by biasing top gate electrode 161 to a top-gate-0 voltage (VT0), bottom gate electrode 108 to a bottom-gate-0 voltage (VB0), drain electrode 168 to a drain-0 voltage (VD0), and the source electrode 168 to ground (0 V). Although the values suitable for VT0, VB0, and VD0 are implementation specific, some embodiments may specify nominal values of VT0, VB0, and VD0 as 1.0 V, −0.5 V, and −1.0 V respectively. The forward biased junction between transistor channel 162 and drain electrode 168 creates positive charges that are trapped and stored in trapping layer 104 of body 302.

In the read mode, read mode voltages, e.g., the read mode voltages shown in FIG. 11 are applied to the appropriate terminals, the drain current of the cell is compared to the current of a reference cell. The current of the selected cell is indicative of the cell's threshold voltage, which is indicative of whether the cell is programmed with negative or positive charge and, therefore, whether the cell is programmed to a “1” or a “0.”

Although disclosures references specific embodiments, various modifications and changes that would be apparent to one of ordinary skill in the art having the benefit of this disclosure would be encompassed with the scope of the disclosed and claimed subject matter. For example, references to specific conductive materials such as polysilicon would encompass other conductive materials such as aluminum, copper, tantalum, titanium, and so forth. Similarly, references to specific dielectrics such as silicon dioxide would encompass alternative dielectrics such as CVD silicon oxide compounds, silicon nitride compounds, and silicon oxynitride compounds. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements.

What is claimed is:

1. A semiconductor device suitable for use as a storage cell, comprising:
a semiconductor body having a top surface and a bottom surface;
a top gate dielectric overlying the semiconductor body top surface;
an electrically conductive top gate electrode overlying the top gate dielectric;
a bottom gate dielectric underlying the semiconductor body bottom surface;
an electrically conductive bottom gate electrode underlying the bottom gate dielectric; and
a charge trapping layer, comprising a plurality of shallow charge traps, overlying the top or underlying the bottom surface of the semiconductor body.

2. The device of claim 1, wherein the charge trapping layer comprises a material selected from the group consisting of aluminum oxide, silicon nitride, and silicon nanoclusters.

3. The device of claim 1, wherein the charge trapping layer is intermediate between the bottom gate dielectric and the bottom surface of the semiconductor body.

4. The device of claim 1, wherein the semiconductor body is substantially single crystal silicon.

5. The device of claim 1, wherein the top gate dielectric differs from the bottom gate dielectric with respect to at least one characteristic selected from the group of characteristics consisting of effective oxide thickness and material.

6. The device of claim 1, wherein the top gate electrode differs from the bottom gate electrode with respect to at least one characteristic selected from the group of characteristics consisting of thickness, material, conductivity, work function, length, and width.

7. The device of claim 1, further comprising:
source/drain regions laterally displaced on either side of the semiconductor body and aligned to the top gate electrode;
isolation regions adjacent to the source/drain regions;
a buried oxide (BOX) layer underlying the bottom gate electrode; and
a semiconductor substrate underlying the BOX layer;
wherein:
the charge trapping layer comprises a layer of a trapping material selected from the group consisting of aluminum oxide, silicon nitride, and a silicon nanoclusters layer comprising a plurality of silicon nanoclusters;
the charge trapping layer is located in close proximity to the interface between the bottom gate dielectric and the semiconductor body;
the top gate dielectric and bottom gate dielectric include at least one material selected from the group consisting of thermally formed silicon dioxide and a high-K dielectric;
the top gate electrode and bottom gate electrode include at least one material selected from the group consisting of polycrystalline silicon, α-silicon, α-germanium, W, Ti, Ta, TiN, TaSiN, and silicide; and
the semiconductor body comprises crystalline silicon.

8. A semiconductor fabrication method comprising:
forming a bottom gate electrode;
forming a bottom gate dielectric overlying the bottom gate electrode;
forming a charge trapping layer, having a density of shallow charge traps exceeding a specified threshold, overlying the bottom gate electrode;
forming a semiconductor body overlying the charge trapping layer;
forming a top gate dielectric overlying the semiconductor body; and
forming a top gate electrode overlying the top gate dielectric.

9. The method of claim 8, wherein forming the bottom gate electrode comprises forming the bottom gate electrode overlying a buried oxide (BOX) layer.

10. The method of claim 8, wherein the bottom gate electrode, the bottom gate dielectric, and the charge trapping layer are formed overlying a semiconductor layer of a donor wafer and wherein the method further includes bonding the donor wafer to a handle wafer.

11. The method of claim 10, further comprising, after said bonding, cleaving the semiconductor layer of the substrate wherein the semiconductor body comprises a portion of the cleaved portion.

12. The method of claim 11, wherein the semiconductor body comprises single crystal silicon.

13. The method of claim 8, wherein forming the charge trapping layer includes forming a layer of a dielectric selected from the group consisting of aluminum oxide and silicon nitride.

14. The method of claim 13, wherein forming the charge trapping layer comprises forming the charge trapping layer by atomic layer deposition.

15. The method of claim 8, wherein forming the charge trapping layer comprises forming a layer of silicon nanoclusters.

16. A method of operating a semiconductor device as a storage cell, comprising:
writing the cell by biasing a top gate electrode overlying a top gate dielectric and a semiconductor body to a first top gate write voltage, biasing a bottom gate electrode underlying a bottom gate dielectric underlying the semiconductor body to a first bottom gate write voltage, biasing a drain electrode laterally positioned adjacent to a transistor channel of the semiconductor body underlying the first gate electrode to a first drain write voltage, and biasing a source terminal laterally positioned adjacent the transistor channel to ground; and
reading the cell by biasing the top gate electrode to a top gate read voltage, biasing the bottom gate electrode to a bottom gate read voltage, biasing the drain electrode to a drain read voltage, and biasing the source terminal laterally positioned adjacent the transistor channel to ground
wherein said writing includes storing charge in a charge trapping layer of the semiconductor device wherein the charge trapping layer is located in close proximity to a surface of the semiconductor body and includes a plurality of charge traps.

17. The method of claim 16 wherein said writing comprises writing a first value and further comprising writing a second value in the storage cell by biasing the top gate electrode to a second top gate write voltage, biasing the bottom gate electrode to a second bottom gate write voltage, biasing the drain electrode to a second drain write voltage, and biasing the source terminal to ground.

18. The method of claim 16 wherein the plurality of charge traps comprise a plurality of shallow hole traps having an activation energy less than approximately 0.3 eV and a density of greater than approximately 1E12 traps/cm².

19. The method of claim 18 wherein said first top gate write voltage is approximately 0.6 V, the first bottom gate write voltage is approximately −2.0 V, the first drain write voltage is approximately 1.8 V, said second top gate write voltage is approximately 1.0 V, said second bottom gate write voltage is approximately −0.5 V, and said second drain write voltage is approximately −1.0 V.

20. The method of claim 19, wherein said top gate read voltage is approximately 0.6 V, said bottom gate read voltage is approximately −1.5 V, and said drain read voltage is approximately 0.2 V.
